(19) United States
(12) Patent Application Publication
(10) Pub. No.: US 2007/0254415 A1
(43) Pub. Date: Nov. 1, 2007

(54) THIN FILM TRANSISTOR SUBSTRATE, METHOD OF MANUFACTURING THE SAME AND METHOD OF MANUFACTURING LIQUID CRYSTAL DISPLAY PANEL INCLUDING THE SAME

(76) Inventors: Hyun Uk Oh, Seongnam-Si (KR); Jin Goo Jung, Goyang-Si (KR)

Correspondence Address: F. CHAU & ASSOCIATES, LLC, 130 WOODBURY ROAD, WOODBURY, NY, 11797, US

(21) Appl. No.: 11/741,184

(22) Filed: Apr. 27, 2007

(30) Foreign Application Priority Data
Apr. 27, 2006 (KR) 10-2006-0038156
Aug. 31, 2006 (KR) 10-2006-0083645

(51) Int. Cl. H01L 21/84; H01L 31/113

(52) U.S. Cl. 438/149; 257/291

(57) ABSTRACT

A thin film transistor substrate, a method of manufacturing the same and a method of manufacturing a liquid crystal display including the same, in which a process of patterning an active pattern and a storage electrode pattern for a storage capacitor and a process of implanting impurity ions into the storage electrode pattern are performed using a single half-tone photo mask, so that the entire manufacturing process can be simplified. A gate insulation film is formed on the active pattern and the storage electrode pattern, so that surface damage that may occur during an ashing process can be prevented. The ion implantation is performed in a state where a stepped photoresist mask is formed to pattern the active pattern and the storage electrode pattern and a photoresist pattern on the storage electrode pattern is then removed, so that the an entire manufacturing process can be simplified.

### CROSS REFERENCE TO RELATED APPLICATIONS

This application claims priority from Korean Patent applications, No. 10-2006-0038156, filed on Apr. 27, 2006, and No. 10-2006-0083645, filed on Aug. 31, 2006, and all the benefits accruing therefrom under 35 U.S.C. §119, the contents of which are herein incorporated by reference in its entirety.

### BACKGROUND OF THE INVENTION

1. Technical Field

The present disclosure relates to a thin film transistor substrate, a method of manufacturing the same and a method of manufacturing a liquid crystal display panel including the same.

2. Discussion of the Related Art

In general, a liquid crystal display (LCD) comprises a thin film transistor (TFT) substrate with pixel electrodes, the TFTs each switching a pixel, and the like formed thereon; a common electrode substrate with color filters, with the common electrodes and the like formed thereon; and liquid crystals sealed between the two substrates. The pixel electrode of the TFT substrate forms a liquid crystal capacitor together with the common electrode of the common electrode substrate. In the LCD, a data signal (grayscale voltage) in accordance with image information is individually supplied to the liquid crystal capacitor of each pixel to control an arrangement of the liquid crystals, and an amount of light being transmitted through the liquid crystals is adjusted in accordance with the controlled arrangement thereof to display an image on the LCD.

The grayscale voltage applied to one pixel should be charged between both ends of the liquid crystal capacitor for a short period of time, and then the charged voltage should be maintained until the next grayscale voltage is input. Thus, a storage capacitor for constantly maintaining a voltage charged in the liquid crystal capacitor is connected with the liquid crystal capacitor within each pixel.

In an LCD including a TFT made of polycrystalline silicon, a polycrystalline silicon thin film is formed on a substrate and then patterned to form an active pattern and a storage electrode pattern. In order to ensure sufficient capacitance, impurity ions are implanted into a storage electrode pattern region through an additional ion implantation process after the above-mentioned patterning process. In such an ion implantation process, a photoresist is applied on the substrate with the active pattern and the storage electrode pattern formed thereon, and then developed and exposed to light to form a photoresist mask. Thereafter, the impurity ions are implanted into the storage electrode pattern region by performing the ion implantation process using the photoresist mask as an ion implantation mask.

As such, there is a problem in that an additional photo mask used for forming an ion implantation mask pattern on a substrate must be fabricated. Further, there is a problem in that surface damage of the active pattern to be used as a channel region of a TFT may be produced, since the processes of fabricating and removing an ion implantation mask using the photoresist should be performed in addition to the patterning process, thereby having an adverse influence on the operation of elements. Furthermore, there is a problem in that both yield reduction and productivity reduction result, due to the increase in the number of process steps that must be employed.

### SUMMARY OF THE INVENTION

Exemplary embodiments of the present invention are provided to solve the aforementioned problems. Accordingly, an object of an exemplary embodiment of the present invention is to provide a thin film transistor (TFT) substrate, a method of manufacturing the TFT substrate, and a method of manufacturing a liquid crystal display (LCD) panel including the same, wherein a process of patterning an active pattern and a storage electrode pattern and a process of implanting impurity ions into the storage electrode pattern are performed with only a single mask, such that the process of manufacturing the TFT substrate can be simplified, a process condition can be easily controlled during the ion implantation process, the deterioration of TFT characteristics can also be prevented, and the capacitance of a storage capacitor can be increased by reducing the interval between a storage electrode pattern connected to a pixel electrode and a storage line.

According to an exemplary embodiment of the present invention, there is provided a method of manufacturing a thin film transistor (TFT) substrate comprising the steps of forming a silicon thin film on a substrate; forming a photoresist pattern on the silicon thin film; removing the silicon thin film to form an active pattern and a storage electrode pattern through an etching process using the photoresist pattern as an etching mask; removing the photoresist pattern on the storage electrode pattern and allowing the photoresist pattern to remain on the active pattern; implanting impurity ions into the storage electrode pattern through an ion implantation process; and removing the photoresist pattern remaining on the active pattern.

The step of forming the photoresist pattern comprises the steps of applying a photoresist on the silicon thin film; exposing the photoresist light; and developing the exposed photoresist, such that a height of the photoresist remaining on the silicon thin film on which the active pattern will be formed is lower than that of the photoresist remaining on the silicon thin film on which the storage electrode pattern will be formed. The stepped photoresist pattern may be formed through light exposure and development using a half-tone mask or a slit mask. More specifically, the step of removing the photoresist pattern on the storage electrode pattern and allowing the photoresist pattern to remain on the active pattern comprises the step of removing the photoresist pattern by the height of the photoresist pattern remaining on the storage electrode pattern through an ashing process.

Impurity ions may be implanted at the dosage of 10¹⁴ to 10¹⁶/cm² under an acceleration energy of 10 to 30 KeV.

The method of manufacturing a TFT substrate according to an exemplary embodiment of the present invention may further comprise the steps of forming a gate insulation film on an entire surface of the substrate after the photoresist pattern on the active pattern has been removed; forming a gate electrode partially overlapping the active pattern, a gate line connecting with the gate electrode and extending in one direction from the gate electrode, and a storage line partially overlapping the storage electrode pattern; and implanting impurity ions into the active pattern at both sides of the gate electrode to form source and drain regions.

The method of an exemplary embodiment of the present invention may further comprise the steps of forming a protection film on the silicon thin film after the step of forming the silicon thin film on the substrate; and removing the protection film after the step of removing the photoresist pattern remaining on the active pattern.

According to an exemplary embodiment of the present invention, there is provided a method of manufacturing a TFT substrate comprising the steps of forming a silicon thin film and a first gate insulation film on a substrate; forming a photoresist pattern on the first gate insulation film; removing the first gate insulation film and the silicon thin film to form an active pattern and a storage electrode pattern through an etching process using the photoresist pattern as an etching mask; removing the photoresist pattern at a region on the storage electrode pattern and allowing the photoresist pattern to remain at a region on the active pattern; implanting impurity ions into the storage electrode pattern through an ion implantation process; and then removing the remaining photoresist pattern.

The step of forming the photoresist pattern comprises the steps of applying a photoresist on the first gate insulation film; exposing the photoresist to light; and developing the photoresist such that a height of the photoresist remaining on the first gate insulation film on which the active pattern will be formed is lower than that of the photoresist remaining on the first gate insulation film on which the storage electrode pattern will be formed. The stepped photoresist pattern may be formed through light exposure and etching using a half-tone mask or a slit mask. More specifically, the step of removing the photoresist pattern on the storage electrode pattern and allowing the photoresist pattern to remain on the active pattern comprises the step of removing the photoresist pattern by the height of the photoresist pattern remaining on the storage electrode pattern through an ashing process.

The method of an exemplary embodiment of the present invention may further comprise the steps of forming a second gate insulation film on an entire surface of the substrate after the photoresist pattern on the active pattern has been removed; forming on the second gate insulation film a gate electrode partially overlapping the active pattern, a gate line connecting with the gate electrode and extending in one direction from the gate electrode, and a storage line partially overlapping the storage electrode pattern; implanting impurity ions into the active pattern at both sides of the gate electrode to form source and drain regions; and forming an interlayer insulation film on an entire surface of the substrate with the gate electrode formed thereon.

The method of an exemplary embodiment of the present invention may further comprise the step of removing the first gate insulation film on the storage electrode pattern after the step of removing the photoresist pattern at a region on the storage electrode pattern and allowing the photoresist pattern to remain at a region on the active pattern.

According to an exemplary embodiment of the present invention, there is provided a method of manufacturing a TFT substrate, comprising the steps of forming an active pattern and a storage electrode pattern on a substrate; forming a gate insulation film the thickness of which on the storage electrode pattern is less than that on the active pattern; and implanting impurity ions into the storage electrode pattern.

The step of forming a gate insulation film the thickness of which on the storage electrode pattern is smaller than that on the active pattern comprises the steps of forming the gate insulation film on the substrate with the active pattern and the storage electrode pattern formed thereon; forming a photoresist mask pattern with a region above the storage electrode pattern exposed; and removing a portion of the gate insulation film at the exposed region. At this time, the step of implanting impurity ions into the storage electrode pattern may comprise the steps of performing an ion implantation process using the photoresist mask pattern as an ion implantation mask; and removing the photoresist mask pattern.

According to an exemplary embodiment of the present invention, there is provided a TFT substrate comprising a substrate; an active pattern and a storage electrode pattern that are formed on the substrate to have source, drain and channel regions; a first gate insulation film formed on the active pattern and the storage electrode pattern; a gate electrode partially overlapping the channel region; a second gate insulation film for insulating the active pattern and the gate electrode from each other; a gate line connecting with the gate electrode and extending in one direction from the gate electrode; a storage line partially overlapping the storage electrode pattern; a source electrode connected to the source region; a source line connecting with the source electrode and extending in the other direction from the source electrode; and a drain electrode connected to the drain region and partially overlapping the storage line.

According to an exemplary embodiment of the present invention, there is provided a method of manufacturing a liquid crystal display panel comprising the steps of providing a lower substrate including a TFT formed with a channel region in an active pattern, a pixel electrode connected to the TFT, and a storage line overlapping the pixel electrode and a storage electrode pattern by performing the steps of removing a portion of a silicon thin film formed on a substrate to form the active pattern and the storage electrode pattern through a patterning process using a photoresist mask and implanting impurity ions into the storage electrode pattern after removing the photoresist mask on the storage electrode pattern; providing an upper substrate including a color filter and a common electrode in correspondence with the lower substrate; and bonding and sealing the lower and upper substrates to face each other and injecting liquid crystals between the substrates.

Preferably, a protection film or a gate insulation film is formed on the silicon thin film.

### BRIEF DESCRIPTION OF THE DRAWINGS

Exemplary embodiments of the present invention will be understood in more detail from the following descriptions taken in conjunction with the accompanying drawings, in which:

FIGS. 1 to 4 are views illustrating a method of manufacturing a thin film transistor (TFT) substrate according to an exemplary embodiment of the present invention;

FIGS. 5 to 9 are sectional views conceptually illustrating a method of fabricating an active pattern and storage electrode pattern according to an exemplary embodiment of the present invention;

FIGS. 10 to 13 are views illustrating a method of manufacturing a TFT substrate according to an exemplary embodiment of the present invention;

FIGS. 14 to 18 are sectional views conceptually illustrating a method of fabricating an active pattern and storage electrode pattern according to an exemplary embodiment of the present invention;

FIGS. 19 to 24 are sectional views conceptually illustrating a method of manufacturing a TFT substrate according to an exemplary embodiment of the present invention;

FIGS. 25 to 28 are sectional views illustrating a method of manufacturing a TFT substrate according to an exemplary embodiment of the present invention; and

FIGS. 29 to 33 are sectional views conceptually illustrating a method of fabricating an active pattern and storage electrode pattern according to an exemplary embodiment of the present invention.

### DETAILED DESCRIPTION OF EXEMPLARY EMBODIMENTS

Hereinafter, exemplary embodiments of the present invention will be described in detail with reference to the accompanying drawings. The present invention is not limited to the exemplary embodiments set forth herein, however, but can be implemented in different forms. Rather, the exemplary embodiments are merely provided to allow the present invention to be completely described herein and to fully convey the scope of the invention to those skilled in the art.

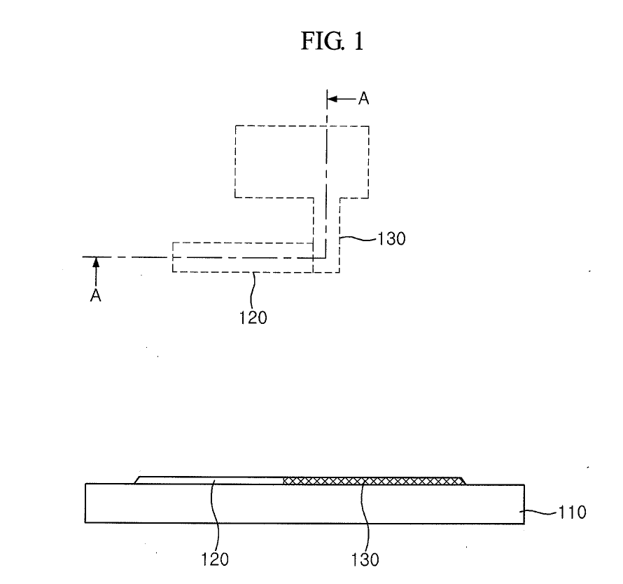

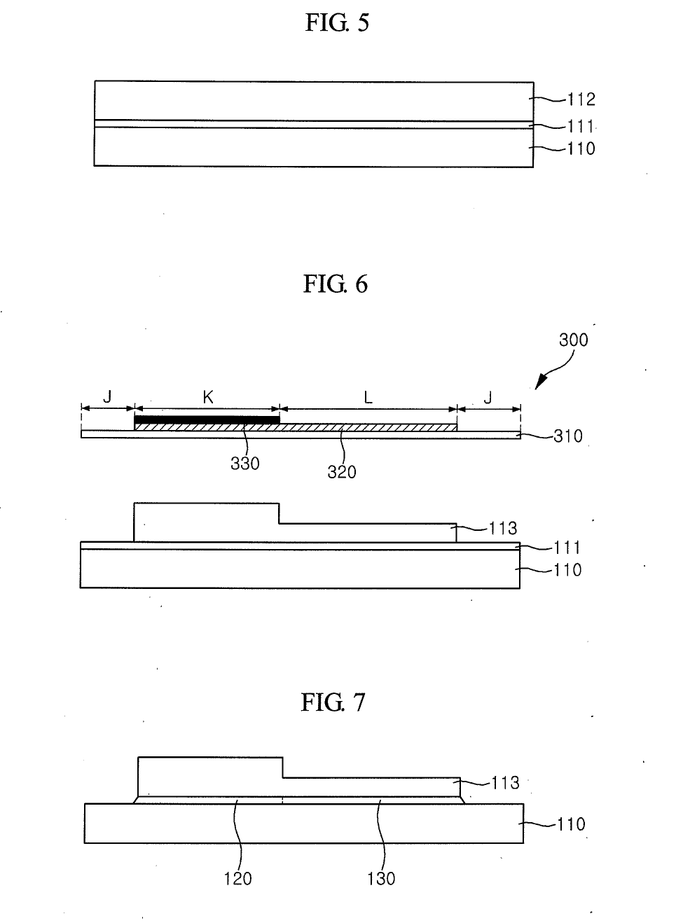

FIGS. 1 to 4 are views illustrating a method of manufacturing a thin film transistor (TFT) substrate according to an exemplary embodiment of the present invention, and FIGS. 5 to 9 are sectional views conceptually illustrating a method of fabricating an active pattern and storage electrode pattern according to the exemplary embodiment of the present invention.

Hereinafter, a method of manufacturing the TFT substrate according to this exemplary embodiment will be described with reference to FIGS. 1 to 9. Each of the following drawings illustrates a unit pixel region having one pixel electrode and one TFT.

As shown in FIG. 1, an active pattern 120 and a storage electrode pattern 130 for a storage capacitor are formed on a transparent insulation substrate 110 and impurity ions are doped into a region of the storage electrode pattern 130.

This will be described in detail with reference to FIGS. 5 to 9.

Referring to FIG. 5, a polycrystalline silicon thin film 111 is first formed on the transparent insulation substrate 110 and a photoresist 112 is then applied on the thin film 111. Such a polycrystalline silicon thin film 111 is formed by depositing an amorphous silicon thin film on the substrate and then performing a crystallization process. That is, the amorphous silicon thin film (a-Si:H) is deposited on the substrate 110 through a low pressure chemical vapor deposition (LPCVD) method or a plasma enhanced chemical vapor deposition (PECVD) method. Thereafter, a dehydrogenation process of removing hydrogen from the amorphous silicon thin film is performed, and the amorphous silicon thin film is then crystallized into the polycrystalline silicon thin film 111 using heat. At this time, it is effective to use a solid phase crystallization (SPC) method and an eximer laser annealing (ELA) method as the crystallization method using heat. Alternatively, a buffer layer (not shown) made of at least one of a silicon oxide film and a silicon nitride film can be formed on the substrate 110, and the polycrystalline silicon thin film 111 formed on the buffer layer.

Referring to FIG. 6, a first photoresist mask pattern 113 is formed by performing a photolithography process using a half-tone photo mask 300. At this time, the first photoresist mask pattern 113 is fabricated in such a manner that a height of the photoresist 112 in a region where the storage electrode pattern 130 will be formed is lower than the height of the photoresist 112 in a region where the active pattern 120 will be formed.

The half-tone photo mask 300 comprises a light transmitting region J through which light is transmitted, a light shielding region K by which light is shielded, and a half-tone region L through which only a portion of the light is transmitted. The half-tone region L may be fabricated to correspond to a size of the storage electrode pattern 130 formed on the transparent insulation substrate 110, and the light shielding region K may be fabricated to correspond to a size of the active pattern 120. A method of fabricating such a half-tone photo mask 300 will be described as follows. A half-tone film 320 is first formed on a transparent substrate 310, and a portion of the half-tone film 320, except the region corresponding to the storage electrode pattern 130 and the active pattern 120, is then removed. Thereafter, a light shielding film 330 is formed on the half-tone film 320, and a portion of the light shielding film 330, except the region corresponding to the active pattern 120, is then removed.

If a light exposure process is performed using the aforementioned half-tone photo mask 300, the photoresist 112 beneath the light transmitting region J is completely exposed to the light, the photoresist 112 beneath the light shielding region K is not exposed to the light any longer, and only a portion of the photoresist 112 beneath the half-tone region L is exposed. Thereafter, as shown in FIG. 6, if a developing process is performed and the photoresist 112 beneath the light transmitting region J is completely removed, only a portion of the exposed photoresist 112 beneath the half-tone region L is removed, and the photoresist 112 beneath the light shielding region K remains unchanged.

Accordingly, the first photoresist mask pattern 113 in which a height of the photoresist 112 remaining on the polycrystalline silicon thin film 111 on which the storage electrode pattern 130 will be formed is lower than that of the photoresist 112 remaining on the polycrystalline silicon thin film 111 on which the active pattern 120 will be formed as described above. Such a height difference may vary according to the light transmissivity of the half-tone film 320 formed on the half-tone region L of the aforementioned half-tone photo mask 300.

Further, this exemplary embodiment is not limited thereto but may employ a slit mask formed with a slit pattern at the half-tone region L instead of the half-tone photo mask 300.

Referring to FIG. 7, an etching process using the first photoresist mask pattern 113 as an etching mask is performed to remove the polycrystalline silicon thin film 111 exposed on the substrate 110 so that the active pattern 120 and the storage electrode pattern 130 are formed. As shown in FIG. 1, the active pattern 120 is fabricated approximately in the form of a straight line extending in a horizontal direction within a region where a TFT will be formed, and the storage electrode pattern 130 is also fabricated approximately in the form of a plate extending from one end of the active pattern 120. Nevertheless, the area, shape and position of the storage electrode pattern 130 can vary according to an aperture ratio and capacitance of a storage capacitor.

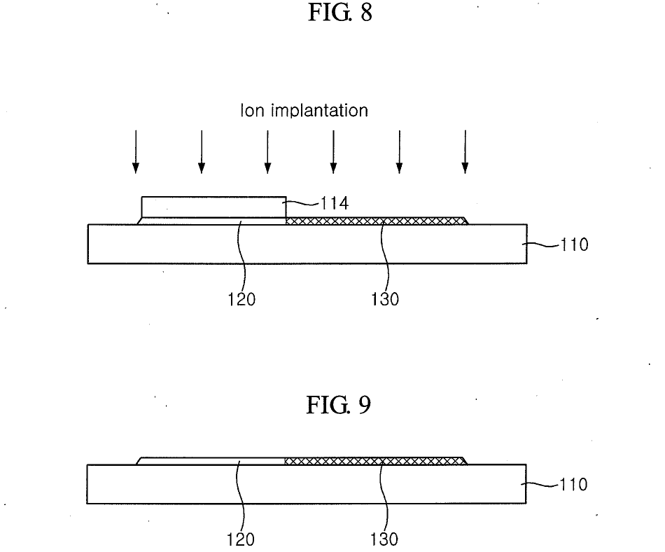

Referring to FIG. 8, a portion of the first photoresist mask pattern 113 is removed through a first ashing process in order to open a region of the storage electrode pattern 130, and a second photoresist mask pattern 114 on which the photoresist remains is formed on a region of the active pattern 120. Thereafter, impurity ions are implanted into the exposed storage electrode pattern 130 through an ion implantation process using the second photoresist mask pattern 114 as an ion implantation mask.

The first ashing process includes dry etching using oxygen plasma. Of course, this exemplary embodiment is not limited to the aforementioned ashing process. That is, the photoresist may be removed using a variety of methods, such as wet etching and photoresist stripping, capable of removing the photoresist.

At this time, the photoresist on a region of the storage electrode pattern 130 is removed through the first ashing process such that process conditions in the subsequent ion implantation process can be easily set. That is, since a surface of the storage electrode pattern 130 is exposed, the setting of an ion projection range (R_{P}) may be easily made and the acceleration energy for ion implantation is not required to be set high. Preferably, N-type impurity ions such as P or As are implanted at the dosage of 10¹⁴ to 10¹⁶/cm² under the acceleration energy of 10 to 30 KeV in the ion implantation process according to this exemplary embodiment. If an acceleration energy lower than 10 to 30 KeV is used, the impurity ions will not be implanted into the storage electrode pattern 130. Alternatively, if an acceleration energy higher than 10 to 30 KeV is used, the impurity ions are implanted into the substrate 110 after passing through the storage electrode pattern 130.

Referring to FIG. 9, the second photoresist pattern 114 is removed through a second ashing process.

As described above, since both a process of forming the active pattern 120 and the storage electrode pattern 130 and a process of implanting the impurity ions into the storage electrode pattern 130 can be performed through a single photolithography process in this exemplary embodiment, the whole process can be simplified. Further, since the photoresist remains on a top surface of the active pattern 120 during the first ashing process, it is possible to prevent the top surface of the active pattern 120 from being damaged due to the ashing process. Accordingly, deterioration of the element characteristics can be prevented.

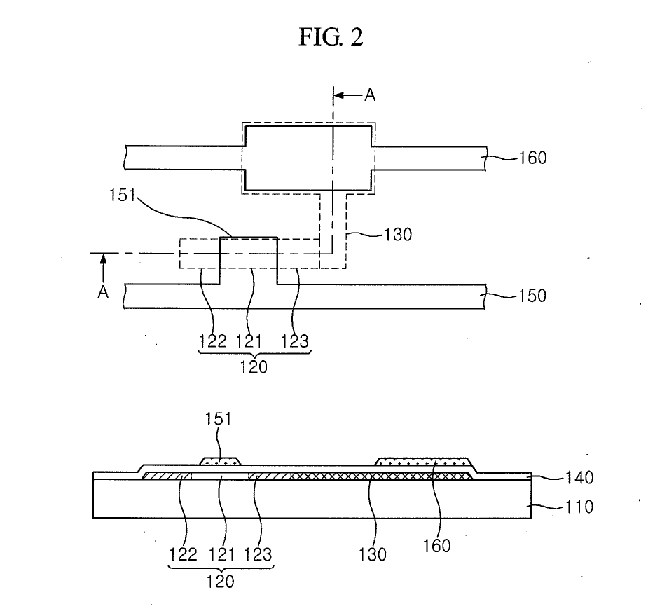

Next, as shown in FIG. 2, a gate insulation film 140 and a first conductive film can be formed on an entire surface of the substrate having the active pattern formed thereon, and the first conductive film can be patterned to form a gate line 150, a gate electrode 151 and a storage line 160.

At this time, an insulation material film such as SiO₂ is used as the gate insulation film 140. Further, at least any one of Mo, Cu, Al, Ti, Cr and an alloy thereof can be used as a first conductive film. The first conductive film may be formed into a single layer structure or a multiple layer structure. Such a first conductive film is patterned to form the gate line 150, the gate electrode 151, and the storage line 160. That is, a photoresist is applied on the first conductive film, and a photoresist mask pattern (not shown) for shielding regions of the gate line 150, the gate electrode 151, and the storage line 160 is then formed through a photolithography process, as shown in FIG. 2. Thereafter, the first conductive pattern at an exposed region is etched through an etching process using the photoresist mask pattern as an etching mask, and the photoresist mask pattern is then removed. Accordingly, the gate line 150 extends in a horizontal direction; the gate electrode 151 protrudes from the gate line 150, such that a portion thereof overlaps with the active pattern 120; and the storage line 160 extends in the same direction as the gate line 150 such that a portion thereof overlaps with the storage electrode pattern 130. The capacitance of a storage capacitor is changed according to the area of an overlapping region between the storage electrode pattern 130 and the storage line 160. Thus, the area of the overlapping region between the storage electrode pattern 130 and the storage line 160 is adjusted so that the capacitance of the storage capacitor can be changed. As shown in FIG. 2, the storage line 160 includes an extension portion connecting between adjacent pixel regions and an electrode portion overlapping with the storage electrode pattern 130. The extension portion is fabricated in the form of a straight line, and the electrode portion is fabricated in the form of a plate. The electrode portion may be fabricated to have the same size as the storage electrode pattern 130. The capacitance of the storage capacitor can be enhanced through the storage electrode pattern 130 doped with the impurity ions. Accordingly, a voltage applied to a liquid crystal capacitor can be kept constant until the next signal voltage is applied to the liquid crystal capacitor.

The gate electrode 151 is positioned at a central region of the active pattern 120, and the active pattern 120 overlapping with the gate electrode 151 is defined as a channel region 121.

The gate electrode 151 is formed, and source and drain regions 122 and 123 are then formed within the active pattern 120 at both sides of the gate electrode 151 through an ion implantation process.

The ion implantation process may be divided into a process of implanting N-type impurity ions and a process of implanting P-type impurity ions, that is, using a different mask for each process, according to a characteristic of the transistor, such as a carrier characteristic, to be formed. That is, a region where the N-type impurity ions will be implanted is opened using a first photoresist mask (not shown), and the N-type impurity ions are then implanted into the active pattern 120 at both sides of the gate electrode 151. Thereafter, a region where the P-type impurity ions will be implanted is opened using a second photoresist mask (not shown), and the P-type impurity ions are then implanted into the active pattern 120 at both sides of the gate electrode 151. Accordingly, N-type and P-type transistors can be individually fabricated on the single substrate 110. Of course, the present invention is not limited thereto. That is, an ion implantation may be performed using an ion barrier film (not shown) formed on the gate electrode 151 as an ion implantation mask, and a plurality of ion implantations, that is, high concentration and low concentration ion implantations, may be performed. For example, the ion barrier film is formed before patterning the first conductive film such that the formed ion barrier film can remain on the gate electrode 151. The ion barrier film may be formed to have a width broader than the gate electrode 151. A high concentration ion implantation layer is formed in the active pattern 120 at both sides of the gate electrode 151 through a high concentration ion injecting process using the ion barrier film as an ion implantation mask. The ion barrier film is removed and a low concentration ion implantation layer is then formed in the active pattern 120 at both sides of the gate electrode 151 through a low concentration ion injecting process. Accordingly, the source and drain regions 122 and 123 each having the high concentration and low concentration ion implantation layers may be formed in the active pattern 120 at both sides of the gate electrode 151.

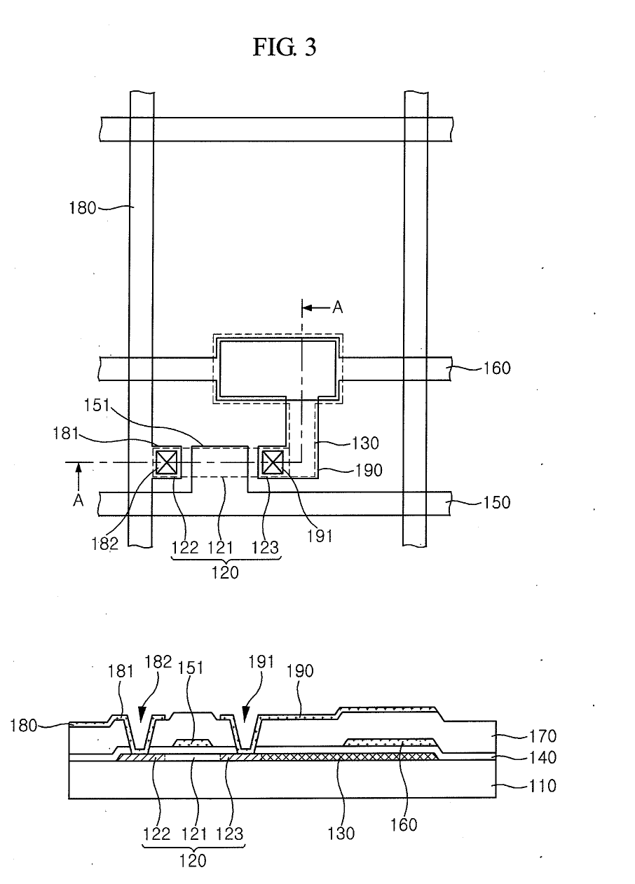

Next, as shown in FIG. 3, an interlayer insulation film 170 is formed on the entire surface of the substrate 110 with the gate electrode 151 formed thereon, and source and drain electrodes 181 and 190 that are connected respectively to the source and drain regions 122 and 123 through the interlayer insulation film 170 are formed.

An inorganic insulation material containing SiO₂ or SiNₓ is used as the interlayer insulation film 170. The interlayer insulation film 170 may be formed into a single layer structure or a multiple layer structure. The interlayer insulation film 170 is formed on an entire structure, and a photoresist is then applied on the interlayer insulation film 170. A photoresist mask pattern for opening the source and drain regions 122 and 123 is formed through a photolithography process using a mask. Source and drain contact holes 182 and 191 for opening portions of the source and drain regions 122 and 123, respectively, are formed through an etching process using the photoresist mask pattern as an etching mask.

A second conductive film is formed on the entire surface of the substrate 110 with the interlayer insulation film 170 formed thereon and then patterned to form a source line 180 that is in the form of a straight line and perpendicular to the gate line 150, a source electrode 181 that protrudes from the source line 180 and connects with the source region 122 through the source contact hole 182, and a drain electrode 190 that connects with the drain region 123 through the drain contact hole 191 such that a portion thereof overlaps with the storage line 160. At least any one of Mo, Cu, Al, Ti, Cr and an alloy thereof is used as the second conductive film. As shown in FIG. 3, the drain electrode 190 includes a connection portion connected to the drain region 123 of the active pattern 120 and an extension portion having the same shape as the storage electrode pattern 130. The value of the capacitance of the storage capacitor can be increased through such an extension portion of the drain electrode 190. Further, the shape of the extension portion is not limited to the foregoing but may be freely changed, so that the capacitance value of the storage capacitor may be freely adjusted. The extension portion of the drain electrode 190 is connected to the pixel electrode through a subsequent process. Since the drain electrode 190 can be used as one electrode plate of the storage capacitor and the storage electrode line 160 can be used as the other electrode plate of the storage capacitor, the thickness of an insulation film between the two electrode plates becomes thinner as compared with a related art. Thus, the capacitance of the storage capacitor can be increased.

Accordingly, since the drain electrode 190 can be used as one electrode plate of the storage capacitor, the interval between the drain electrode 190 and the storage line 160 used as the other electrode plate of the storage capacitor can be reduced.

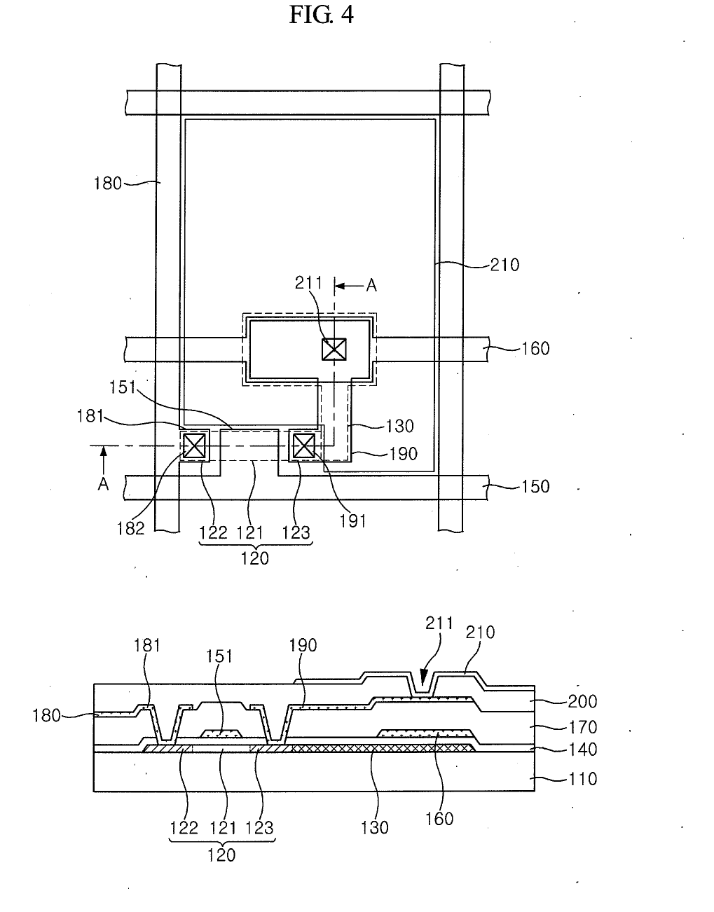

Next, as shown in FIG. 4, a protection film 200 is formed on the entire surface of the substrate 110 with the source and drain electrode 181 and 190 formed thereon, and a pixel electrode 210 connected to the drain electrode 190 is formed on the protection film 200.

The protection film 200 is formed, and a pixel contact hole 211 through which a portion of the drain electrode 190 is exposed is then formed. The protection film 200 is made of an inorganic or organic insulation material. Thereafter, a transparent conductive film containing indium tin oxide (ITO) or indium zinc oxide (IZO) is deposited on an entire structure. The transparent conductive film is patterned to form the pixel electrode 210 that is connected to the drain electrode 190 through the pixel contact hole 211.

Further, the exemplary embodiment of the present invention is not limited to the aforementioned descriptions. That is, a gate insulation film may be formed on a polycrystalline silicon thin film and an active pattern and a storage electrode pattern may be formed; impurity ions may be implanted into the storage electrode pattern; and light leakage may be prevented through a dummy gate line pattern. Hereinafter, a method of manufacturing a TFT substrate according to an exemplary embodiment of the present invention will be described. Some descriptions of this exemplary embodiment overlapping with the aforementioned descriptions will be omitted herein. Further, the descriptions of this exemplary embodiment can be applied to the previous exemplary embodiment.

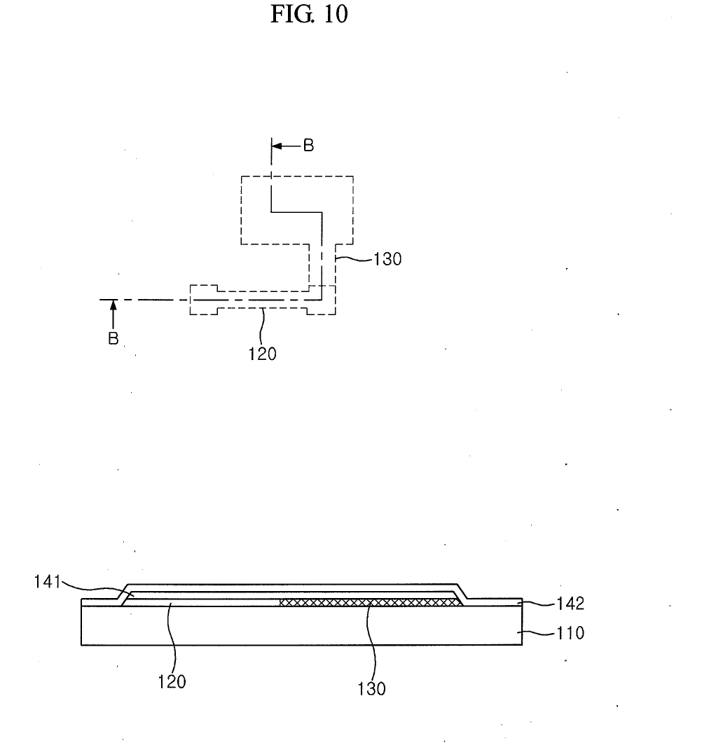

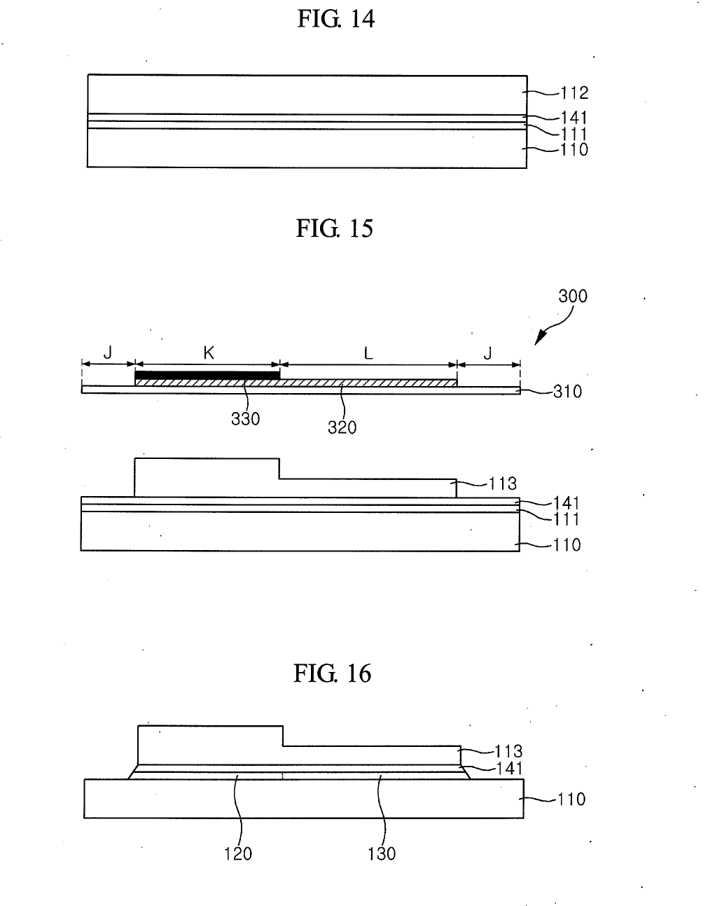

FIGS. 10 to 13 are views illustrating a method of manufacturing a TFT substrate according to an exemplary embodiment of the present invention, and FIGS. 14 to 18 are sectional views conceptually illustrating a method of fabricating an active pattern and storage electrode pattern according to this exemplary embodiment of the present invention.

Hereinafter, a method of manufacturing the TFT substrate according to this exemplary embodiment will be described with reference to FIGS. 10 to 18.

As shown in FIG. 10, an active pattern 120 and a storage electrode pattern 130 doped with impurity ions are formed on a transparent insulation substrate 110, and gate insulation films 141 and 142 are formed on the patterns 120 and 130.

This will be described in detail with reference to FIGS. 14 and 18.

Referring first to FIG. 14, on the transparent insulation substrate 110 are first formed a polycrystalline silicon thin film 111 and a first gate insulation film 141, on which a photoresist 112 is in turn applied.

Referring to FIG. 15, a first photoresist mask pattern 113 is formed through a photolithography process using a half-tone photo mask 300. At this time, the first photoresist mask pattern 113 is fabricated in such a manner that the photoresist 112 in a region where the storage electrode pattern 130 will be formed is lower than the photoresist 112 in a region where the active pattern 120 will be formed.

Referring to FIG. 16, the first gate insulation film 141 and the polycrystalline silicon thin film 111, which are exposed on the substrate 110, are sequentially removed through an etching process using the first photoresist pattern 113 as an etching mask in order to form the active pattern 120 and the storage electrode pattern 130. At this time, the first gate insulation film 141 remains on only regions above the active pattern 120 and the storage electrode pattern 130.

Here, as shown in FIG. 10, the active pattern 120 can be generally fabricated in the form of a straight line extending in a horizontal direction within a region where the TFT will be formed, and extension portions for connecting respectively with source and drain electrodes can be provided at both ends of the active pattern 120. The storage electrode pattern 130 is generally fabricated in the form of a plate extending from one end of the active pattern 120.

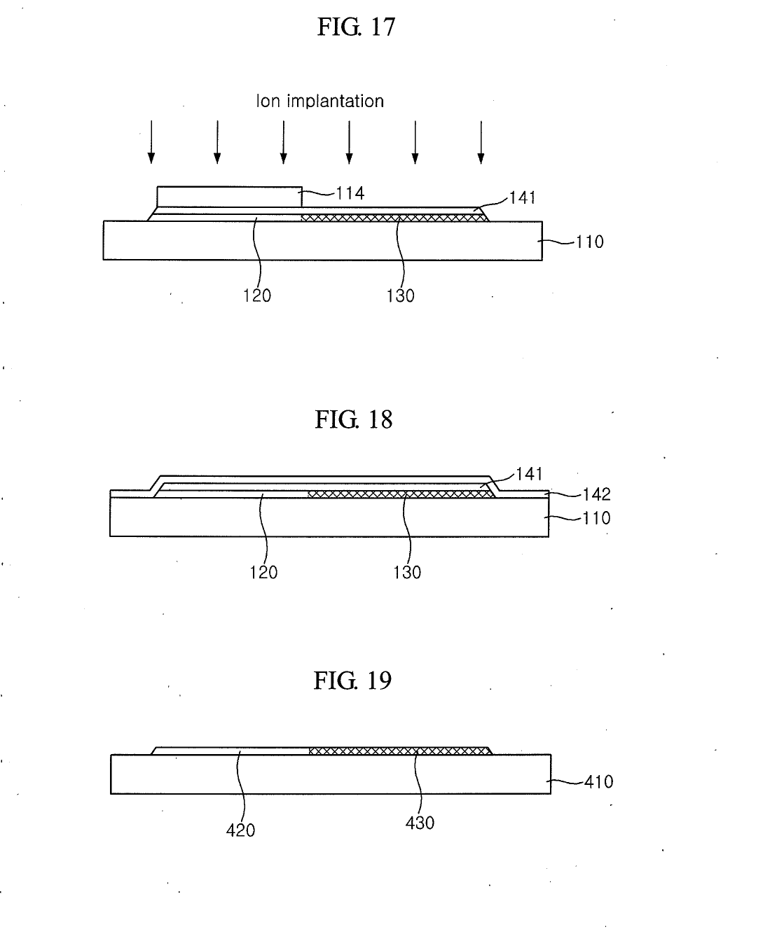

Referring to FIG. 17, a portion of the first photoresist mask pattern 131 is removed through a first ashing process to open an upper region of the storage electrode pattern 130, and a second photoresist mask pattern 114 with the photoresist remaining thereon is formed on the active pattern 120. Thereafter, impurity ions are implanted into the exposed storage electrode pattern 130 through an ion implantation process using the second photoresist mask pattern 114 as an ion implantation mask. At this time, since the first gate insulation film 141 is provided on the storage electrode pattern 130, it is possible to prevent the top surface of the storage electrode pattern 130 from being deteriorated due to the ion implantation operation. In the previously described exemplary embodiment, the process conditions for ion implantation were set with respect to the surface of the storage electrode pattern 130. In this exemplary embodiment, however, the process conditions for ion implantation are set with respect to the surface of the first gate insulation film 141 due to the first gate insulation film 141 provided on the storage electrode pattern 130. For example, the acceleration energy for ion implantation may be increased as compared with the previously described exemplary embodiment in consideration of the thickness of the first gate insulation film 141.

Referring to FIG. 18, the second photoresist pattern 114 is removed through a second ashing process, and a second gate insulation film 142 is formed on the entire pattern.

As described above, since a process of forming the active pattern 120 and the storage electrode pattern 130 and a process of implanting impurity ions into the storage electrode pattern 130 can be performed through a single photolithography process using one mask in this exemplary embodiment, the whole process can be simplified. Further, since the first gate insulation film 141 serves as a protection film on the active pattern 120, it is possible to prevent the surface of the active pattern 120 from being damaged due to plasma used in the ashing process.

The second photoresist mask pattern 114 is removed and a second gate insulation film 142 is then applied on the entire structure. Of course, the gate insulation films 141 and 142 are not limited to the foregoing but may include a plurality of layers. At this time, the first and second gate insulation films 141 and 142 may be formed of the same materials or different materials. For example, a silicon oxide film may be used as the first and second gate insulation films 141 and 142. Otherwise, a silicon oxide film may be used as the first gate insulation film 141, while a silicon nitride film may be used as the second gate insulation film 142.

When a target thickness of the gate insulation films 141 and 142, that is, the thickness between a gate electrode and a channel region, is assumed to be 1, the thickness of the first gate insulation film 141 may be within a range of 0.1 to 0.9 and the thickness of the second gate insulation film 142 may also be within a range of 0.1 to 0.9. This can prevent the overall thickness of the gate insulation film from being increased. Here, the first gate insulation film 141 functions to prevent the active pattern 120 from being damaged and the second gate insulation film 142 functions to insulate the gate electrode 151 and the active pattern 120 from each other. Thus, each of the first and second gate insulation films 141 and 142 may have a variety of thickness ranges to perform its own role, but are not limited to the previous description.

Of course, this exemplary embodiment is not limited to the aforementioned descriptions. A protection film (not shown) is formed on the polycrystalline silicon thin film 111, the active pattern 120 and the storage electrode pattern 130 are then formed, and impurity ions are implanted into the storage electrode pattern 130. After the impurity ions have been implanted, the second photoresist mask pattern is removed. At this time, the protection film functions to protect the surface of the underlying storage electrode pattern 130 when the impurity ions are implanted and to protect the surface of the active pattern 120 when the second photoresist mask pattern is removed. That is, the protection film may perform the same function as the aforementioned first gate insulation film 141. After the protection film has been removed, the gate insulation film may be deposited on the entire structure.

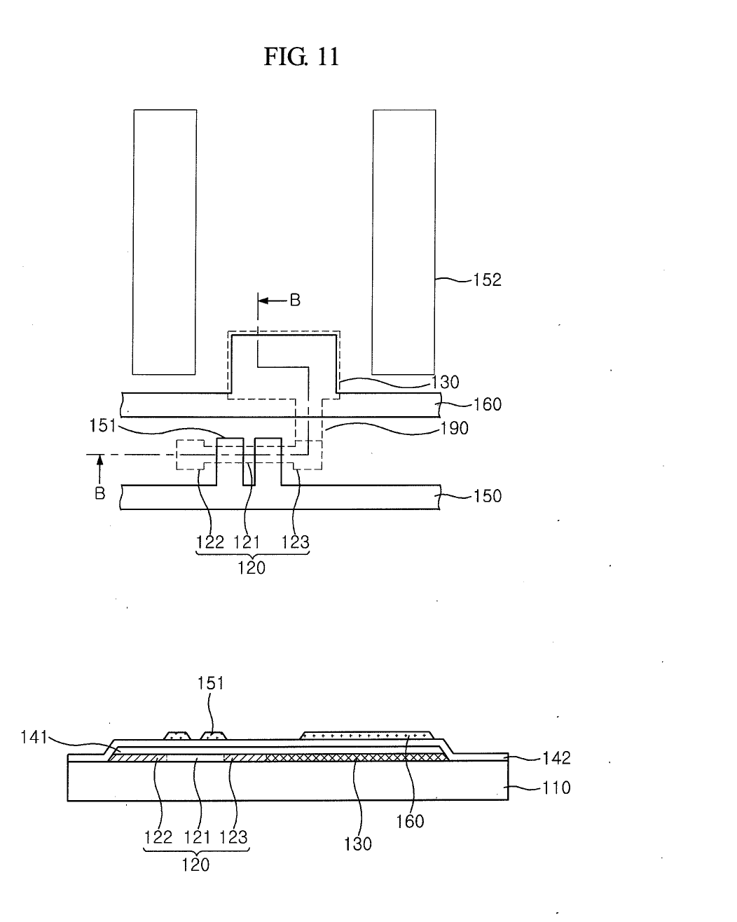

Next, as shown in FIG. 11, it is preferred that a first conductive film be formed on an entire surface of the substrate 110 with the first and second gate insulation films 141 and 142 formed on the active pattern 120 and that the first conductive film be patterned to form a gate line 150, a gate electrode 151 and a storage line 160. A dummy pattern 152 may then be formed together at boundary regions between pixels to prevent light leakage.

A photoresist is applied on the first conductive film formed on the second gate insulation film 142, and a photoresist mask pattern (not shown) for shielding regions of the gate line 150, the gate electrode 151, the dummy pattern 152, and the storage line 160 is then formed through a photolithography process as shown in FIG. 11. Thereafter, the first conductive film 141 at an exposed region is etched through an etching process using the photoresist mask pattern as an etching mask, and the photoresist mask pattern is then removed.

Accordingly, the gate line 150 is formed to extend in a horizontal direction; the gate electrode 151 is formed to protrude from the gate line 150, such that a portion thereof overlaps with the active pattern 120; the storage line 160 is formed to extend in the same direction as the gate line 150, such that a portion thereof overlaps with the storage electrode pattern 130; and the dummy pattern 152 is spaced apart from the gate line 150 and the storage line 160 at the boundary regions between pixels and extends in a direction perpendicular to the gate and storage lines. The width of the above dummy pattern 152 may vary according to an aperture ratio of the pixel. The dummy pattern 152 may be fabricated to have a line width one to three times broader than that of the gate or source line 150 or 180. As such, in this exemplary embodiment, a light leakage phenomenon at the boundary regions between pixels can be prevented through the dummy pattern 152. Thus, a film serving to prevent the light leakage need not be formed on a common electrode substrate corresponding to the TFT substrate.

As shown in FIG. 11, the gate electrode 151 includes first and second protrusions protruding from the gate line 150. The first and second protrusions are positioned at a central region of the active pattern 120, and the first and second gate insulation films 141 and 142 are provided between the first and second protrusions and the active pattern 120. Further, the storage line 160 includes an extension portion connecting between adjacent pixel regions and an electrode portion extending from the extension portion to overlap with the storage electrode pattern 130 as shown in FIG. 11.

The gate electrode 151 is formed as described above, and source and drain regions 122 and 123 are then formed in the active pattern 120 at both sides of the gate electrode 151 through an ion implantation process. The source and drain regions 122 and 123 may be formed by implanting N-type or P-type impurity ions with an extended region in the form of a rectangle at an end of the active pattern 120.

In addition, a heat treatment process of activating the impurity ions may be further performed after the ion implantation process of this exemplary embodiment.

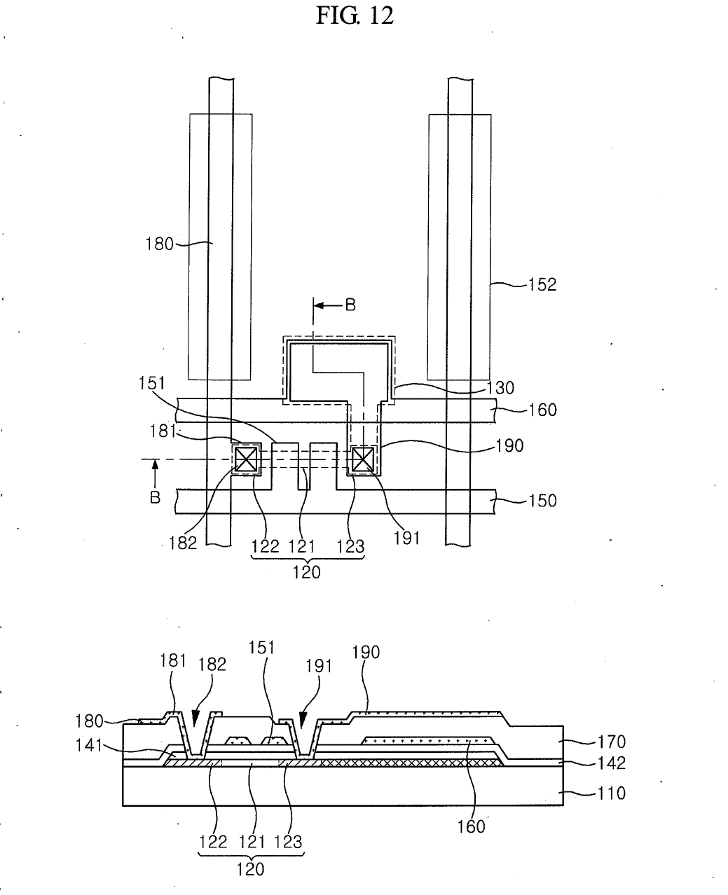

Next, as shown in FIG. 12, an interlayer insulation film 170 is formed on an entire surface of the substrate 110 with the gate electrode 151 and the dummy pattern 152 formed thereon, and a portion of the interlayer insulation film 170 is etched to form source and drain contact holes 182 and 191 for exposing portions of the source and drain regions 122 and 123, respectively. A second conductive film is formed on an entire surface of the interlayer insulation film 170 formed with the contact holes 182 and 191 and then patterned to form the source line 180 that is in the form of a line and perpendicular to the gate line 150, a source electrode 181 that protrudes from the source line 180 and connects with the source region 122 through the source contact hole 182, and a drain electrode 190 that connects with the drain region 123 through the drain contact hole 191, such that a portion thereof overlaps with the storage line 160. Accordingly, the TFT can be manufactured. In the case of the source line 180, a portion thereof may overlap with the dummy pattern 152, and the source line 180 may extend inwardly into the dummy pattern 152, thereby serving to prevent light leakage.

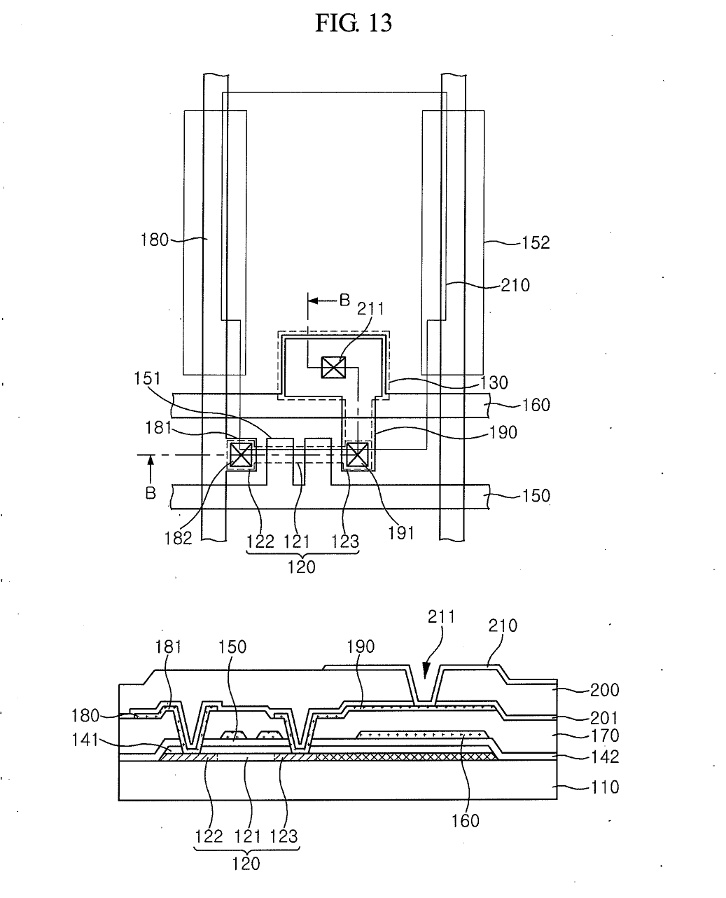

Next, as shown in FIG. 13, a passivation film 201 and a protection film 200 are formed on the entire surface of the substrate 110 with the source and drain electrodes 181 and 190 formed thereon, and portions of the passivation film 201 and the protection film 200 are removed to form a pixel contact hole 211. A transparent conductive film is deposited on the protection film 200 formed with the pixel contact hole 211 and then patterned to form a pixel electrode 210.

Here, the passivation film 201 is formed on an entire surface of the interlayer insulation film 170 formed with the source line 180, the source electrode 181 and the drain electrode 190, and is deposited at a temperature of 300 to 500® C. or more. Each of the passivation films 201 and the protection film 200 functions to protect the underlying TFT.

This exemplary embodiment is not limited to the aforementioned descriptions. That is, a translucent pattern may also be formed at a portion of the pixel electrode. In other words, the translucent pattern may be formed at a TFT region and a storage electrode pattern region for a storage capacitor, and a light reflection film for reflecting light may be formed on the translucent pattern. Accordingly, the TFT substrate may be used for a translucent LCD panel.

Further, the exemplary embodiment of the present invention is not limited to the aforementioned descriptions. That is, the number of masks for manufacturing a TFT substrate can be reduced using a mask having a translucent region. Hereinafter, a method of manufacturing a TFT substrate according to an exemplary embodiment of the present invention in which source and drain electrodes and a pixel pattern are simultaneously formed to reduce the number of masks for manufacturing the TFT substrate will be described. Some descriptions of this exemplary embodiment overlapping with the aforementioned descriptions will be omitted herein. Further, the descriptions of this exemplary embodiment can be applied to the previously described embodiments.

FIGS. 19 to 24 are sectional views conceptually illustrating a method of manufacturing a TFT substrate according to an exemplary embodiment of the present invention.

Referring to FIG. 19, a polycrystalline silicon thin film is formed on a transparent insulation substrate 410, and an active pattern 420 and a storage electrode pattern 430 are then formed through an etching process using a photoresist mask pattern. At this time, a glass substrate, a plastic substrate or the like may be used as the transparent insulation substrate 410. The photoresist mask pattern formed on the storage electrode pattern 430 is removed through an ashing process. Thereafter, impurity ions are implanted into the storage electrode pattern 430 through an ion implantation process using the photoresist mask pattern in which the photoresist on the storage electrode pattern 430 is removed.

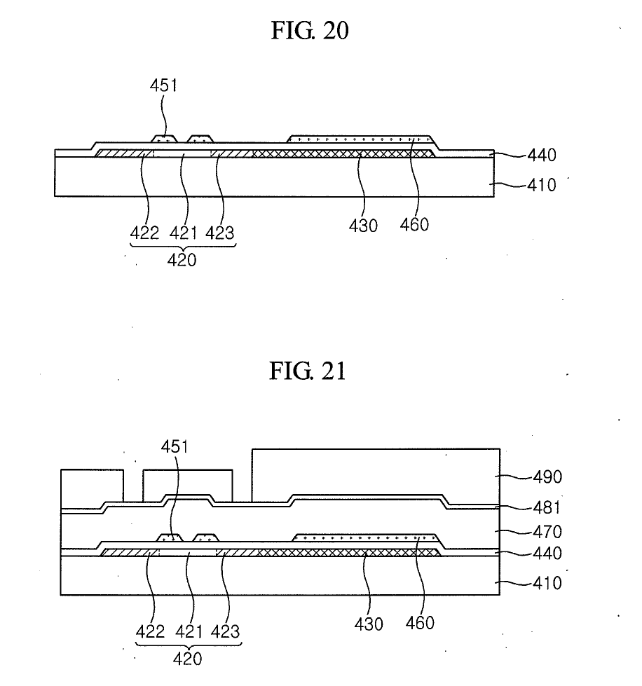

Referring to FIG. 20, a gate insulation film 440 and a first conductive film are formed on an entire surface of the substrate 410 with the active pattern 420 formed thereon. The first conductive film is patterned to form a gate line (not shown) that extends in a horizontal direction, a gate electrode 451 that protrudes from the gate line to a central region of the active pattern 420, and a storage line 460 that extends in the same direction as the gate line such that a portion thereof overlaps with the storage electrode pattern 430. The impurity ions are implanted into a region of the active pattern 420 at both sides of the gate electrode 451 to form source and drain regions 422 and 423, respectively.

Referring to FIG. 21, an interlayer insulation film 470 and a transparent conductive film 481 are formed on the entire surface of the substrate 410 with the gate electrode 451 formed thereon. A photoresist is applied on a pixel electrode, and a first photoresist mask pattern 490 is then formed through a photolithography process using a translucent photo mask having translucent regions of a half-tone pattern and a slit pattern. That is, the photoresist at a region where the pixel electrode will be formed is not removed but remains during a developing process. A portion of the photoresist on the source and drain regions 422 and 423, that is, on regions where source and drain contact holes 491 and 492 will be formed, is removed during the developing process to allow the underlying transparent conductive film 481 to be exposed. Only an upper portion of the photoresist on the other regions is removed during the developing process such that the photoresist on the other regions remain lower than the photoresist at a region where the pixel electrode will be formed.

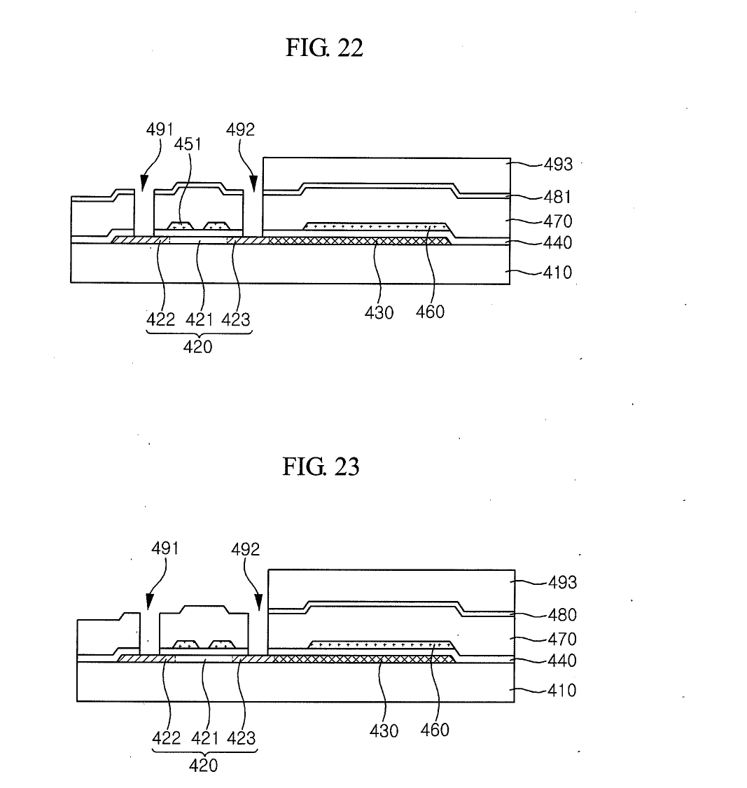

Referring to FIG. 22, the transparent conductive film 481, the interlayer insulation film 470 and the gate insulation film 440, which are exposed through the first photoresist mask pattern 490, are sequentially removed using the first photoresist mask pattern 490 as an etching mask in order to form the source and drain contact holes 491 and 492 for opening the source and drain regions 422 and 423, respectively. Thereafter, the first photoresist mask pattern 490, except at a region where the pixel electrode will be formed is removed to form a second photoresist mask pattern 493. If the height of the first photoresist mask pattern 490 is lowered as a whole through an ashing process, the photoresist remains in the region where the pixel electrode will be formed and the photoresist of the other regions is removed.

Referring to FIG. 23, the transparent conductive film 481, shown in FIG. 22, on an exposed region is removed using the second photoresist mask pattern 493 as an etching mask to form the pixel electrode 480.

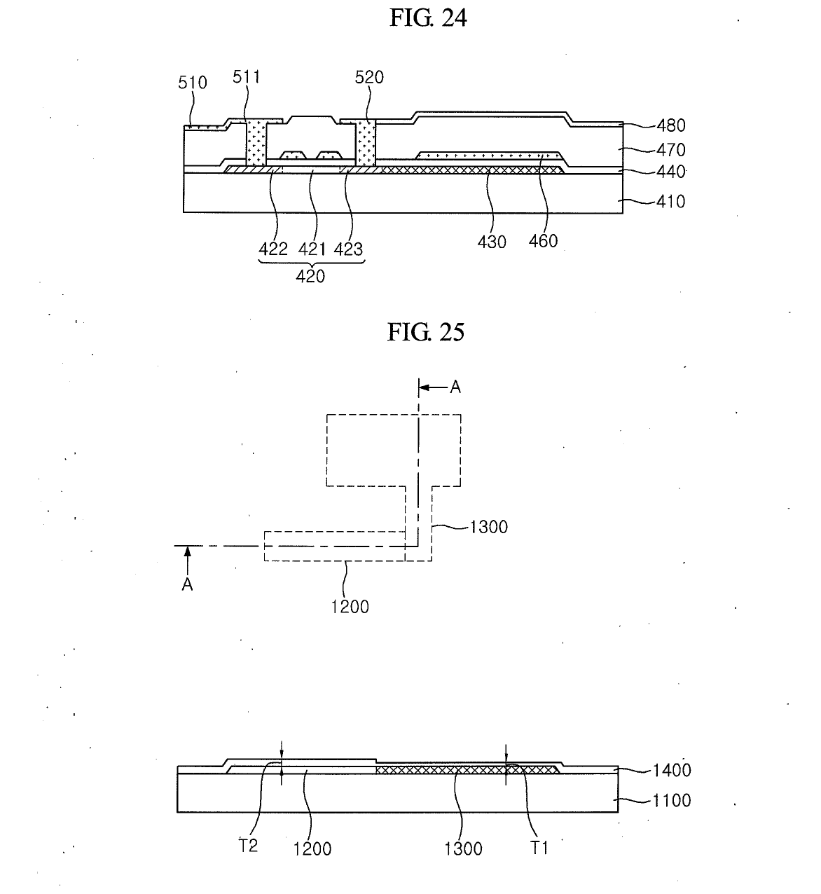

Referring to FIG. 24, a second conductive film is formed on the entire surface of the substrate 410 with the pixel electrode 480 formed thereon. The second conductive film is patterned to form a source line 510 that extends in a direction perpendicular to the gate line, a source electrode 511 that protrudes from the source line 510 and connects with the source region 422 through the source contact hole 491, shown in FIG. 23, and a drain electrode 520 that connects to the drain region 423 and the pixel electrode 480 through the drain contact hole 492, shown in FIG. 23. At this time, a side region of the pixel electrode 480 be connected to the drain electrode 520. The second photoresist mask pattern formed on the pixel electrode 480 is removed after the source and drain electrodes 511 and 520 have been formed. Accordingly, since a process of forming a pixel contact hole for connecting the drain and pixel electrodes 520 and 480 with each other can be omitted through the aforementioned process, the whole process can be simplified.

Further, the present invention is not limited to the above descriptions of exemplary embodiments, and the capacitance of the storage capacitor can be increased by reducing the thickness of a gate insulation film on the storage electrode pattern. Hereinafter, a method of manufacturing a TFT substrate according to an exemplary embodiment of the present invention will be described with reference to the following drawings. Portions of this exemplary embodiment overlapping with the aforementioned descriptions will be omitted herein. Further, the descriptions of this exemplary embodiment can be applied to the previously described exemplary embodiments.

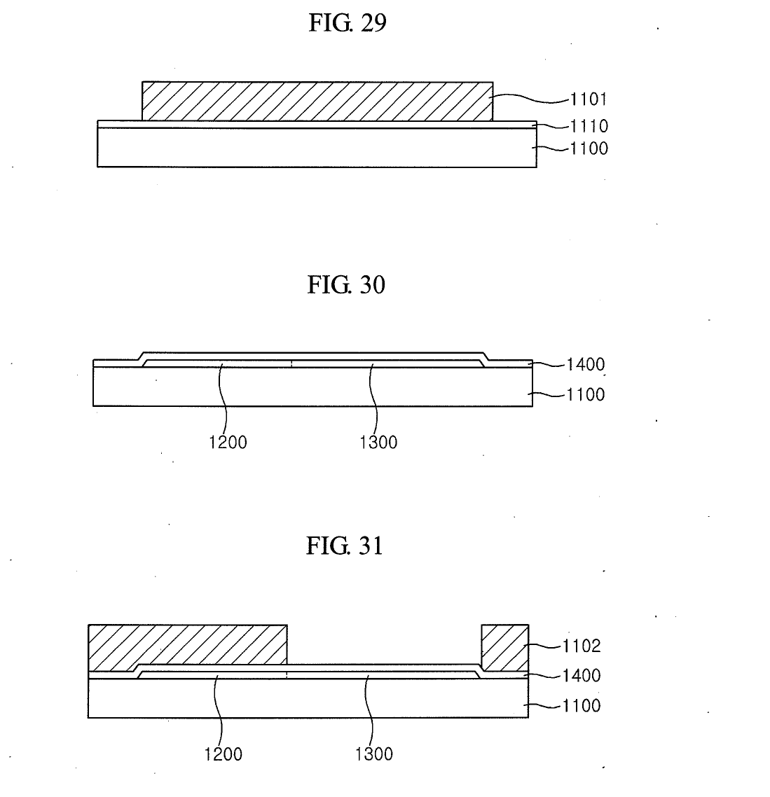

FIGS. 25 to 28 are sectional views illustrating a method of manufacturing a TFT substrate according to an exemplary embodiment of the present invention, and FIGS. 29 to 33 are sectional views conceptually illustrating a method of fabricating an active pattern and storage electrode pattern according to the exemplary embodiment of the present invention.

Hereinafter, a method of manufacturing the TFT substrate according to this exemplary embodiment will be described with reference to FIGS. 25 to 33. Each of the following drawings illustrates a unit pixel region having one pixel electrode and one TFT.

As shown in FIG. 25, an active pattern 1200 and a storage electrode pattern 1300 for a storage capacitor are formed on a transparent insulation substrate 1100, a gate insulation film 1400 is formed on the entire structure, and impurity ions are doped into a region of the storage electrode pattern 1300. In this exemplary embodiment, the gate insulation film 1400 is fabricated so that a thickness T1 of the gate insulation film 1400 on the storage electrode pattern 1300 is smaller than a thickness T2 of the gate insulation film 1400 in the other regions.

This will be described in detail with reference to FIGS. 29 to 33.

First, referring to FIG. 29, a polycrystalline silicon thin film 1110 is formed on the transparent insulation substrate 1100. A photoresist is applied on the polycrystalline silicon thin film 1110, and a first photoresist mask pattern 1101 is then formed by performing a photolithography process using a mask. The first photoresist mask pattern 1101 opens a region except the region where the active pattern 1200 and the storage electrode pattern 1300 will be formed.

Referring to FIG. 30, the exposed polycrystalline silicon thin film 1110 is patterned by performing an etching process using the first photoresist mask pattern 1101 as an etching mask to form the active pattern 1200 and the storage electrode pattern 1300. The first photoresist mask pattern 1101 is removed, and the gate insulation film 1400 is then formed on the substrate 1100 with the active pattern 1200 and the storage electrode pattern 1300 formed thereon. As the gate insulation film 1400, an insulative film including a silicone oxide film and/or a silicon nitride film is used.

Referring to FIG. 31, a photoresist is applied on the gate insulation film 1400, and a second photoresist mask pattern 1102 opening the region of the storage electrode pattern 1300 is then formed by performing a photolithography process using a mask.

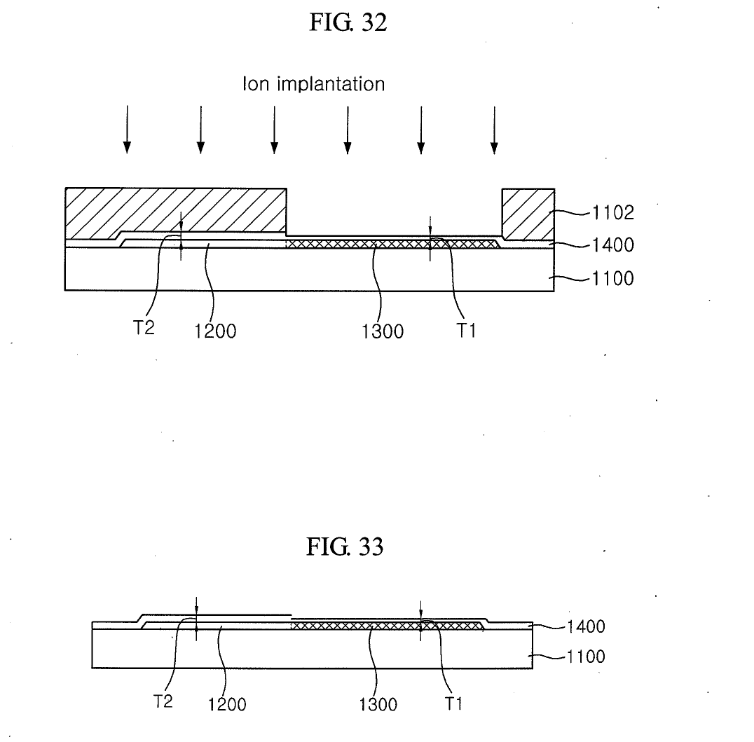

Referring to FIG. 32, a portion of the gate insulation film 1400 in the exposed region, that is, a top of the storage electrode pattern 1300, is removed by performing an etching process using the second photoresist mask pattern 1102 as an etching mask. Subsequently, impurity ions are implanted into the region of the storage electrode pattern 1300 by performing an ion implantation process using the second photoresist mask pattern 1102 as an ion implantation mask.

Next, as shown in FIG. 33, if the second photoresist mask pattern 1102 is removed, the active pattern 1200 and the storage electrode pattern 1300, into which impurities are implanted, are formed and, thus, the gate insulation film 1400 is formed so that the thickness T1 of the gate insulation film 1400 on the storage electrode pattern 1300 is smaller than that of the other regions.

As such, in this exemplary embodiment, the gate insulation film 1400 on the storage electrode pattern 1300 is removed using the second photoresist mask pattern 1102 implanting the impurity ions into the region of the storage electrode pattern 1300, so that its thickness can be reduced. Accordingly, the thickness T1 of the gate insulation film 1400 on the storage electrode pattern 1300 can be smaller than the thickness T2 of the gate insulation film 1400 in the other regions. At this time, assuming that the thickness T2 of the gate insulation film 1400 in the other regions is 1, the thickness T1 of the gate insulation film 1400 on the storage electrode pattern 1300 can be 0.1 to 0.9. The storage electrode pattern 1300 is connected to a drain region 1230 of a pixel electrode 2100, and a TFT 1200 is fabricated through the subsequent processes.

Accordingly, an aperture ratio can be enhanced by reducing a size of the storage electrode pattern 1300 in this exemplary embodiment. Here, the capacitance of a storage capacitor is in inverse proportion to a spacing distance between the storage electrode pattern 1300 and a storage line 1600 fabricated through the subsequent processes, and is in proportion to the overlapping area of the storage electrode pattern 1300 and the storage line 1600. The spacing distance between the storage electrode pattern 1300 and the storage line 1600 is determined by the thickness of the gate insulation film 1400 provided in a region therebetween. Thus, if the thickness of the gate insulation film 1400 is reduced as in this exemplary embodiment, the capacitance of the storage capacitor can be increased in inverse proportion thereto. This can reduce the overlapping area of the storage electrode pattern 1300 and the storage line 1600 in a case where the same capacitance is maintained. As such, since the size of the storage electrode pattern 1300 and the storage line 1600 can be reduced while maintaining a desired capacitance of the storage capacitor, an aperture ratio can be enhanced.

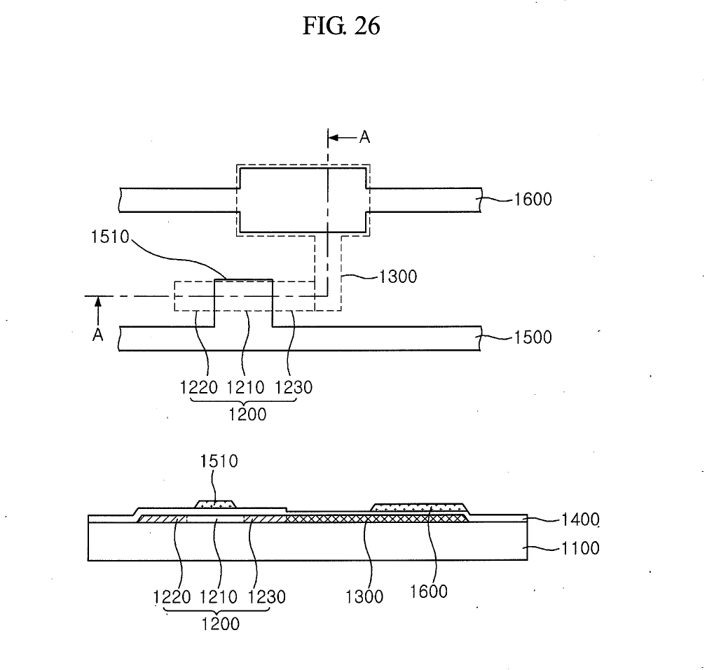

A first conductive film can be formed on the entire surface of the substrate 1100 having the active pattern 1200, the storage electrode pattern 1300, and the gate insulation film 1400 formed thereon and can be patterned to form a gate line 1500, a gate electrode 1510 and the storage line 1600, as shown in FIG. 26.

Then, after the gate electrode 1510 is formed, source and drain regions 1220 and 1230 are formed within the active pattern 1200 at both sides of the gate electrode 1510 by performing an ion implantation process.

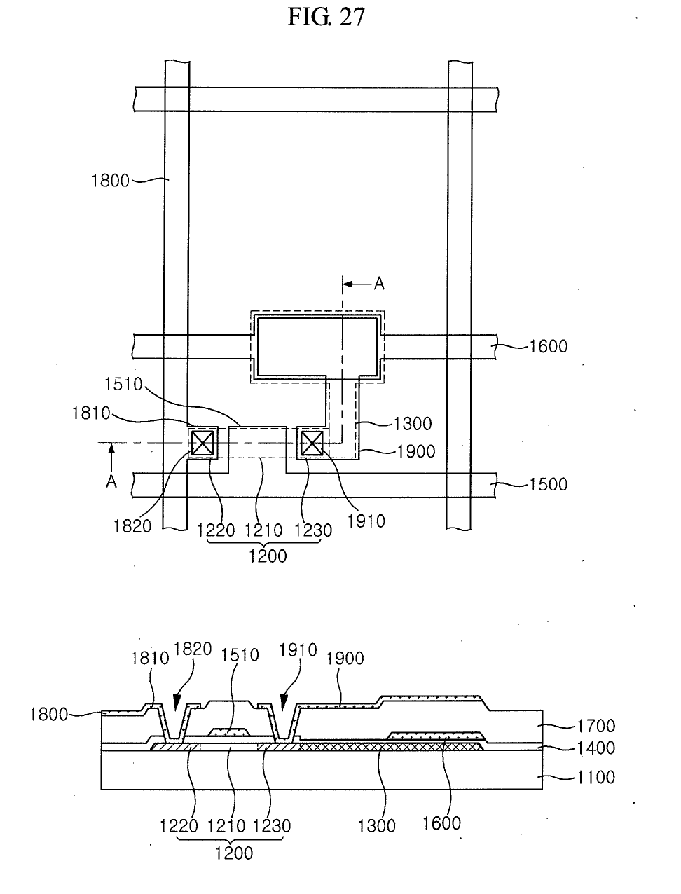

Next, as shown in FIG. 27, an interlayer insulation film 1700 is formed on the entire surface of the substrate 1100 having the gate electrode 1510 formed thereon. Then, there are formed a source line 1800, and source and drain electrodes 1810 and 1900, which pass through the interlayer insulation film 1700 and are respectively connected to the source and drain regions 1220 and 1230.

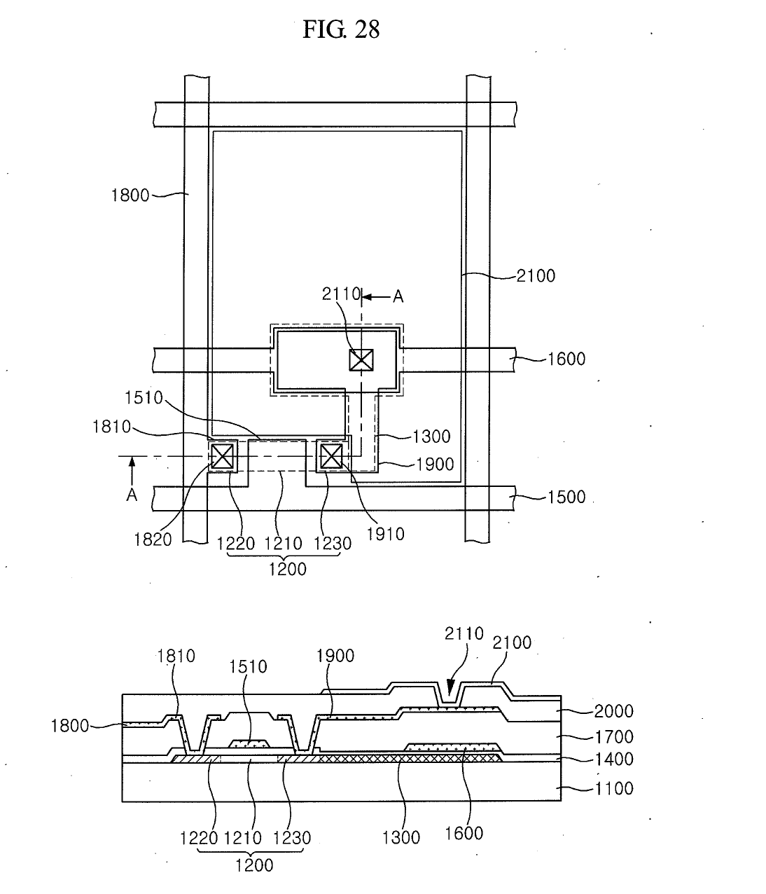

Next, as shown in FIG. 28, a protection film 2000 is formed on the entire surface of the substrate 1100 having the source and drain electrodes 1810 and 1900 formed thereon, and a pixel electrode 2100 connected to the drain electrode 1900 is formed on the protection film 2000.

In addition, exemplary embodiments of the present invention are not limited to the aforementioned description. That is, after a gate insulation film is formed on a polycrystalline silicon thin film, active and storage electrode patterns may be formed, impurity ions may be implanted into the storage electrode pattern, and light leakage may be prevented through a dummy gate line pattern. Further, a thickness of a gate insulation film on the storage electrode pattern may be reduced using a slit or translucent mask.

A TFT and a pixel electrode are formed on a substrate through the aforementioned method of the exemplary embodiment, and a TFT substrate for an LCD can be manufactured. Although a TFT formed on a TFT substrate used in an LCD has been described by way of example in the aforementioned exemplary embodiment, the present invention is not limited thereto. That is, the present invention may be applied to pixel driving transistors and driving circuits in a variety of flat panel displays, such as LTPS and OLED.

Further, an LCD panel is preferably fabricated by bonding and sealing a common electrode substrate and a TFT substrate so configured and then injecting liquid crystals in a region between the two substrates. At this time, the common electrode substrate is fabricated by forming red, green and blue color filters on a transparent insulation substrate and forming a common electrode thereon. Here, the color filters correspond to pixels of the TFT substrate, respectively. In addition, a predetermined spacer may be further formed to maintain a cell gap between the two substrates when bonding the two substrates together. Furthermore, a sealing member, such as a sealant, is preferably used to bond and seal the two substrates.

Alternatively, an LCD may be fabricated in such a manner that a TFT substrate and a common electrode substrate are first provided, the liquid crystals are dripped on one substrate and a sealing member is applied along an edge of the other substrate, and the two substrates are then bonded and sealed.

As described above, according to exemplary embodiments of the present invention, since a process of patterning an active pattern and a storage electrode pattern and a process of implanting impurity ions into a storage electrode pattern are performed using a single mask, the whole manufacturing process can be simplified.

Further, ion implantation is performed in a state where an active pattern and a storage electrode pattern are patterned using a photoresist pattern and the photoresist pattern on the storage electrode pattern is then removed. Thus, the process conditions for ion implantation can be easily set.

Furthermore, a protection or gate insulation film is formed on an active pattern and a storage electrode pattern such that the damage of pattern surfaces that may occur during an ashing process for removing a photoresist can be prevented. Thus, operating characteristics of the element can be enhanced.

In addition, a dummy pad is formed at boundary regions between pixels when forming a gate line. Thus, light leakage can be prevented.

While the present invention has been described in connection with the exemplary embodiments, it will be understood by those skilled in the art that various modifications and changes can be made thereto without departing from the spirit and scope of the invention as defined by the appended claims.

What is claimed is:

1. A method of manufacturing a thin film transistor (TFT) substrate, comprising the steps of:
forming a silicon thin film on a substrate;
forming a photoresist pattern on the silicon thin film;
removing portions of the silicon thin film to form an active pattern and a storage electrode pattern through an etching process using the photoresist pattern as an etching mask;
removing the photoresist pattern on the storage electrode pattern and allowing the photoresist pattern to remain on the active pattern;
implanting impurity ions into the storage electrode pattern through an ion implantation process; and
removing the photoresist pattern remaining on the active pattern.

2. The method as claimed in claim 1, wherein the step of forming the photoresist pattern comprises the steps of:
applying a photoresist on the silicon thin film; and
light exposing and developing the photoresist such that a height of the photoresist remaining on the silicon thin film on which the active pattern will be formed is lower than a height of the photoresist remaining on the silicon thin film on which the storage electrode pattern will be formed.

3. The method as claimed in claim 2, wherein the stepped photoresist pattern is formed through light exposure and development using one of a half-tone mask and a slit mask.

4. The method as claimed in claim 2, wherein the step of removing the photoresist pattern on the storage electrode pattern and allowing the photoresist pattern to remain on the active pattern comprises the step of removing the photoresist pattern by the height of the photoresist pattern remaining on the storage electrode pattern through an ashing process.

5. The method as claimed in claim 1, wherein impurity ions are implanted at the dosage of 10¹⁴ to 10¹⁶/cm² under the acceleration energy of 10 to 30 KeV.

6. The method as claimed in claim 1, further comprising the steps of:
forming a gate insulation film on an entire surface of the substrate after the photoresist pattern on the active pattern has been removed;
forming a gate electrode partially overlapping the active pattern, a gate line connecting with the gate electrode and extending in one direction from the gate electrode, and a storage line partially overlapping the storage electrode pattern; and
implanting impurity ions into the active pattern at both sides of the gate electrode to form source and drain regions.

7. The method as claimed in claim 1, further comprising the steps of:
forming a protection film on the silicon thin film after the step of forming the silicon thin film on the substrate; and
removing the protection film after the step of removing the photoresist pattern remaining on the active pattern.

8. A method of manufacturing a TFT substrate, comprising the steps of:
forming a silicon thin film and a first gate insulation film on a substrate;
forming a photoresist pattern on the first gate insulation film;
removing portions of the first gate insulation film and the silicon thin film to form an active pattern and a storage electrode pattern through an etching process using the photoresist pattern as an etching mask;
removing the photoresist pattern at a region on the storage electrode pattern and allowing the photoresist pattern to remain at a region on the active pattern;
implanting impurity ions into the storage electrode pattern through an ion implantation process; and
removing the remaining photoresist pattern.

9. The method as claimed in claim 8, wherein the step of forming the photoresist pattern comprises the steps of:
applying a photoresist on the first gate insulation film; and
light exposing and developing the photoresist such that a height of the photoresist remaining on the first gate insulation film on which the active pattern will be formed is lower than a height of the photoresist remaining on the first gate insulation film on which the storage electrode pattern will be formed.

10. The method as claimed in claim 9, wherein the stepped photoresist pattern is formed through light exposed and etching using a half-tone mask or a slit mask.

11. The method as claimed in claim 9, wherein the step of removing the photoresist pattern on the storage electrode pattern and allowing the photoresist pattern to remain on the active pattern comprises the step of removing the photoresist pattern by the height of the photoresist pattern remaining on the storage electrode pattern through an ashing process.

12. The method as claimed in claim 8, further comprising the steps of:
forming a second gate insulation film on an entire surface of the substrate after the photoresist pattern on the active pattern has been removed;
forming on the second gate insulation film a gate electrode partially overlapping the active pattern, a gate line connecting with the gate electrode and extending in one direction from the gate electrode, and a storage line partially overlapping the storage electrode pattern;
implanting impurity ions into the active pattern at both sides of the gate electrode to form source and drain regions; and
forming an interlayer insulation film on an entire surface of the substrate with the gate electrode formed thereon.

13. The method as claimed in claim 8, further comprising the step of removing the first gate insulation film on the storage electrode pattern after the step of removing the photoresist pattern at a region on the storage electrode pattern and allowing the photoresist pattern to remain at a region on the active pattern.

14. A method of manufacturing a TFT substrate, comprising the steps of:
forming an active pattern and a storage electrode pattern on a substrate;
forming a gate insulation film a thickness of which on the storage electrode pattern is smaller than a thickness on the active pattern; and
implanting impurity ions into the storage electrode pattern.

15. The method as claimed in claim 14, wherein the step of forming a gate insulation film the thickness of which on the storage electrode pattern is smaller than a thickness on the active pattern comprises the steps of:
forming the gate insulation film on the substrate with the active pattern and the storage electrode pattern formed thereon;
forming a photoresist mask pattern with a region above the storage electrode pattern exposed; and
removing a portion of the gate insulation film at the exposed region.

16. The method as claimed in claim 15, wherein the step of implanting impurity ions into the storage electrode pattern comprises the steps of:
performing an ion implantation process using the photoresist mask pattern as an ion implantation mask; and
removing the photoresist mask pattern.

17. A TFT substrate, comprising:
a substrate;
an active pattern and a storage electrode pattern that are formed on the substrate to have source, drain and channel regions;
a first gate insulation film formed on the active pattern and the storage electrode pattern;
a gate electrode partially overlapping the channel region;
a second gate insulation film for insulating the active pattern and the gate electrode from each other;
a gate line connecting with the gate electrode and extending in one direction from the gate electrode;
a storage line partially overlapping the storage electrode pattern;
a source electrode connected to the source region;
a source line connecting with the source electrode and extending in the other direction from the source electrode; and
a drain electrode connected to the drain region and partially overlapping the storage line.

18. A method of manufacturing a liquid crystal display panel, comprising the steps of:
providing a lower substrate including a TFT formed with a channel region in an active pattern, a pixel electrode connected to the TFT, and a storage line overlapping the pixel electrode and a storage electrode pattern by performing the steps of removing a portion of a silicon thin film formed on a substrate to form the active pattern and the storage electrode pattern through a patterning process using a photoresist mask and implanting impurity ions into the storage electrode pattern after removing the photoresist mask on the storage electrode pattern;
providing an upper substrate including a color filter and a common electrode and corresponding to the lower substrate; and
bonding and sealing the lower and upper substrates to face each other and injecting liquid crystals between the substrates.

19. The method as claimed in claim 18, wherein one of a protection film and a gate insulation film is formed on the silicon thin film.
